(19) United States
(12) Patent Application Publication
(10) Pub. No.: US 2024/0332234 A1
(43) Pub. Date: Oct. 3, 2024

(54) BUMP MANUFACTURING METHOD AND IMPRINT DIE USED IN SAME

(71) Applicant: Panasonic Intellectual Property Management Co., Ltd., Osaka (JP)

(72) Inventors: KEIKO IKUTA, Osaka (JP); KIYOKAZU ITOI, Osaka (JP); DAISUKE SAKURAI, Osaka (JP)

(21) Appl. No.: 18/738,095

(22) Filed: Jun. 10, 2024

Related U.S. Application Data
(63) Continuation of application No. PCT/JP2022/027255, filed on Jul. 11, 2022.

(30) Foreign Application Priority Data
Dec. 21, 2021 (JP) 2021-207164

(51) Int. Cl. H01L 23/00; B22F 7/08; H05K 3/40

(52) U.S. Cl. CPC H01L 24/11; B22F 7/08; H05K 3/4007; B22F 2998/10; H01L 2224/11312; H01L 2224/1147

(57) ABSTRACT

A method for manufacturing a bump on an object includes preparing an object including an electrode pad and a resist layer including an opening portion on the electrode pad. Further, the method includes inserting a needle having a diameter smaller than an opening diameter of the opening portion to the opening portion to come into contact with the electrode pad, filing the opening portion with a metal particle dispersion by transferring the metal particle dispersion to the needle, and sintering the metal particle dispersion filling the opening portion.

### TECHNICAL FIELD

The present disclosure relates to a bump manufacturing method and an imprint die used in the same.

### BACKGROUND ART

In order to achieve both densification of a semiconductor element and an increase in number of pins of electrode terminals, a pitch and an area have been reduced the electrode terminals of the semiconductor element.

Normally, in flip-chip mounting, bumps made of solder are formed on the electrode terminal provided in the semiconductor element such as a system LSI, a memory, or a CPU. The bumps face connection terminals of a mounting board, and are pressed and heated. The bumps and the connection terminals are mounted by being connected to each other.

However, as the demand for reducing the pitch between the electrodes becomes stricter, a solder bridge defect occurs. This is a defect that the solder bump is melted by heating and are connected to the adjacent solder bump.

On the other hand, a method for mounting by solid phase diffusion bonding such as an ultrasonic bonding method or a thermocompression bonding method by using sharp-edged fine metal bumps made of, for example, gold, copper, or the like instead of the solder bumps has been proposed. According to this method, since the bumps are bonded without being melted, the solder bridge defect can be avoided, and it is possible to cope with the reduced pitch.

As a method for forming a sharp-edged fine metal bump, there is a method for opening a hole having a sharp-edged bump shape in a resist layer formed on a semiconductor element and forming a bump in the hole by metal plating (for example, PTL 1).

### CITATION LIST

### Patent Literature

PTL 1: Unexamined Japanese Patent Publication No. 2019-102763

### SUMMARY OF THE INVENTION

In the above method, electrochemical plating is used to form the bump. At this time, it is difficult to uniformly control a current density distribution that changes depending on a position and a density of the electrode pad on the semiconductor element. As a result, filling of the sharp-edged bump shaped hole with plating becomes uneven, and the shape of the bump may vary. The shape of the bump is easily influenced by the position and density of the electrode on the semiconductor element or a circuit board.

In addition, after the bump is formed, a seed layer for forming a plating layer is removed. At this time, a part of the bump is also removed together with the seed layer, and this point also causes variation in the bump shape.

An object of the present disclosure is to provide a bump manufacturing method capable of forming a bump having a stable shape, and an imprint die used in the same.

A bump manufacturing method of the present disclosure includes preparing an object that includes an electrode pad and a resist layer including an opening portion on the electrode pad, inserting a needle having a diameter smaller than an opening diameter of the opening portion to the opening portion to come into contact with the electrode pad, filing the opening portion with a metal particle dispersion by transferring the metal particle dispersion to the needle, and sintering the metal particle dispersion filling the opening portion.

An imprint die of the present disclosure includes a needle, and an introduction path that supplies a liquid to the needle.

According to the bump manufacturing method of the present disclosure, since the bump is formed by transferring the metal particle dispersion to the needle to fill the opening portion with the metal particle dispersion and sintering the metal particle dispersion, the bump having a stable shape can be formed while the influence of the position and density of the electrode is avoided.

### BRIEF DESCRIPTION OF THE DRAWINGS

FIG. 1 is a diagram illustrating a semiconductor element of the present disclosure prepared for bump formation.

FIG. 2A is a diagram illustrating a step of preparing the semiconductor element in FIG. 1.

FIG. 2B is a diagram illustrating the step of preparing the semiconductor element in FIG. 1, subsequently to FIG. 2A.

FIG. 2C is a diagram illustrating the step of preparing the semiconductor element in FIG. 1, subsequently to FIG. 2B.

FIG. 2D is a diagram illustrating the step of preparing the semiconductor element in FIG. 1, subsequently to FIG. 2C.

FIG. 3A is a diagram illustrating a section of an imprint die used in the present disclosure, and corresponds to line A-A in FIG. 3B.

FIG. 3B is a diagram illustrating a planar configuration of the imprint die of the present disclosure.

FIG. 4A is a diagram illustrating a method for manufacturing the imprint die of the present disclosure.

FIG. 4B is a diagram illustrating the method for manufacturing the imprint die, subsequently to FIG. 4A.

FIG. 4C is a diagram illustrating the method for manufacturing the imprint die, subsequently to FIG. 4B.

FIG. 4D is a diagram illustrating the method for manufacturing the imprint die, subsequently to FIG. 4C.

FIG. 5A is a diagram for describing a bump manufacturing method of the present disclosure.

FIG. 5B is a diagram for describing the bump manufacturing method, subsequently FIG. 5A.

FIG. 5C is a diagram for describing the bump manufacturing method, subsequently FIG. 5B.

FIG. 5D is a diagram for describing the bump manufacturing method, subsequently FIG. 5C.

FIG. 5E is a diagram for describing the bump manufacturing method, subsequently FIG. 5D.

FIG. 5F is a diagram for describing the bump manufacturing method, subsequently FIG. 5E.

FIG. 6 is a diagram illustrating an imprint die according to a modification of an exemplary embodiment of the present disclosure.

### DESCRIPTION OF EMBODIMENT

Hereinafter, an exemplary embodiment of the present disclosure will be described with reference to the drawings.

### <Semiconductor Element 1>

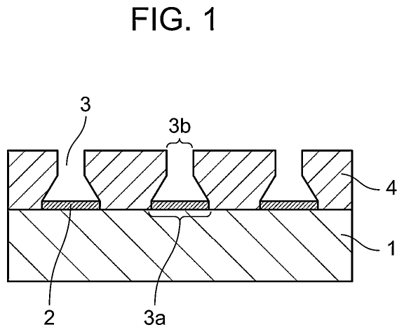

FIG. 1 is a sectional view schematically illustrating semiconductor element 1 prepared for bump formation in the present exemplary embodiment. Semiconductor element 1 includes a plurality of electrode pads 2 and resist layer 4 including opening portions 3 on electrode pads 2. Opening portion 3 is a sharp-edged-shaped space in which opening 3b on an opposite side is smaller than opening 3a on electrode pad 2 side. A diameter of opening 3a is a value falling within a range of electrode pad 2, and is, for example, 5 μm to 20 μm. In addition, a diameter of opening 3b is a diameter more than or equal to 3 μm and is less than the diameter of opening 3b.

Opening portion 3 is formed according to a position of electrode pad 2, and is desirably formed with a pitch of 1.5 times or more the diameter of opening 3a. In addition, a height of opening portion 3 is preferably twice or less the diameter of opening 3a.

By doing this, even though a bump formed to have a shape and a position corresponding to opening portion 3 is pressed in a mounting step, the bump can be compressed and deformed while avoiding interference with an adjacent bump. In addition, it is also possible to suppress deviation of a mounting position due to buckling deformation of the bump.

### <Preparation Method for Semiconductor Element 1>

An example of a method for forming resist layer 4 including opening portion 3 on semiconductor element 1 including electrode pad 2 will be described.

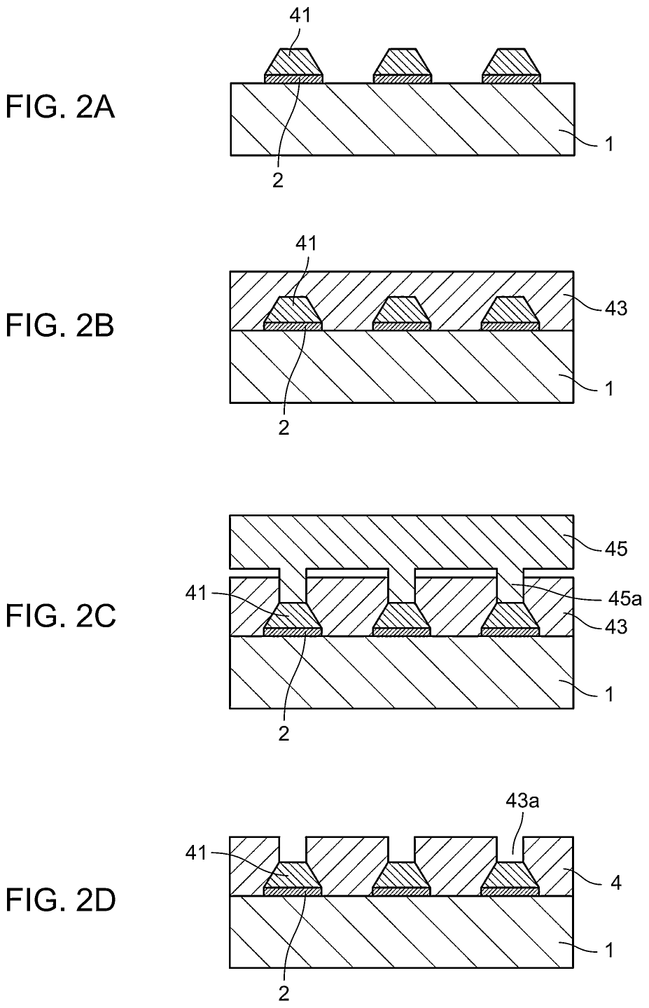

First, as illustrated in FIG. 2A, a volatile resin layer 41 is formed on each of electrode pads 2 provided on semiconductor element 1. Resin layer 41 has a sharp-edged shape that is narrowed in a direction away from electrode pad 2 side.

Subsequently, as illustrated in FIG. 2B, resist coating layer 43 is applied on semiconductor element 1 to cover resin layers 41. Subsequently, as illustrated in FIG. 2C, die 45 in which protrusions 45a are provided to face electrode pads 2 is pressed against coated resist coating layer 43. At this time, protrusions 45a and resin layers 41 are pressurized to come into contact with each other. In this state, resist coating layer 43 is cured.

Subsequently, as illustrated in FIG. 2D, die 45 is removed. As a result, resist layer 4 in which opening portions 43a are provided on resin layers 41 is obtained. Thereafter, resin layers 41 are selectively dissolved through opening portion 43a, and thus, semiconductor element 1 in FIG. 1 in which resist layer 4 including opening portions 3 on electrode pads 2 is provided is obtained.

### <Imprint Die 15>

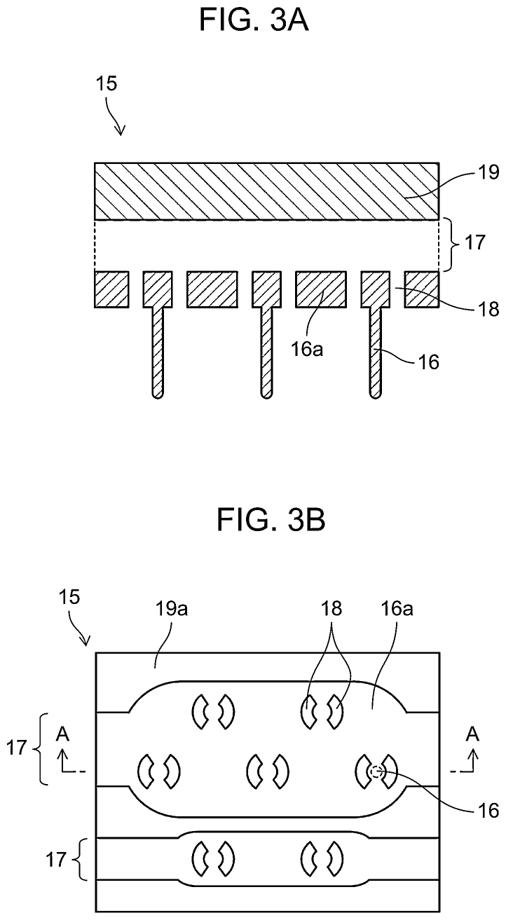

Next, imprint die 15 used in the present exemplary embodiment will be described. FIGS. 3A and 3B are schematic sectional views and plan views of imprint die 5. FIG. 3A corresponds to line A-A in FIG. 3B. FIG. 3B illustrates that each element is viewed as transparent. However, dimensions in FIGS. 3A and 3B do not necessarily correspond to each other.

Imprint die 15 includes needles 16, needle base portion 16a having a plate shape and holding needle 16, and base 19, and flow path 17 is formed between needle base portion 16a and base 19. As illustrated in FIG. 3B, a side surface of flow path 17 is defined by wall portion 19a of base 19 that does not appear in FIG. 3A. In addition, needle base portion 16a has introduction paths 18 near a root of needle 16. Introduction paths 18 are connected to flow path 17.

Needles 16 are provided to correspond to electrode pads 2 of semiconductor element 1 forming the bumps. Accordingly, similarly to opening portion 3, the needle is desirably formed with a pitch of 1.5 times or more the diameter of opening 3a.

With the above configuration, imprint die 15 supplies a liquid from flow path 17 to introduction paths 18. The liquid is transmitted to needles 16 through introduction paths 18.

### <Method for Manufacturing Imprint Die 15>

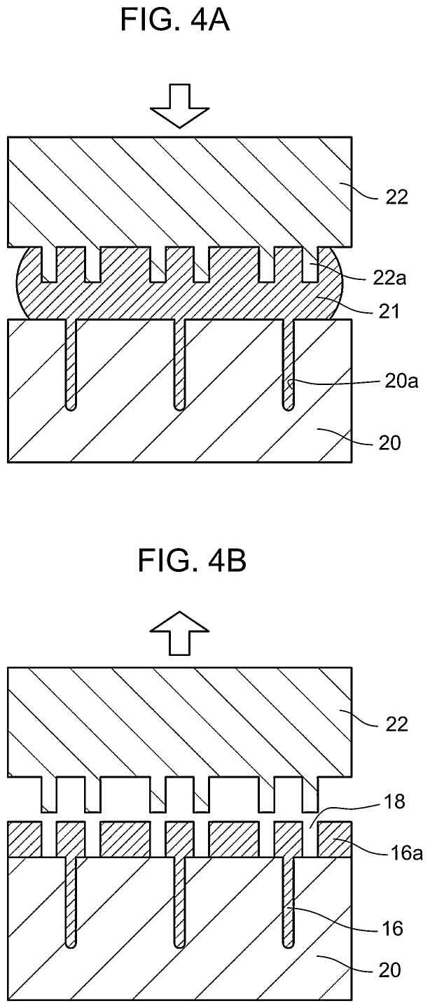

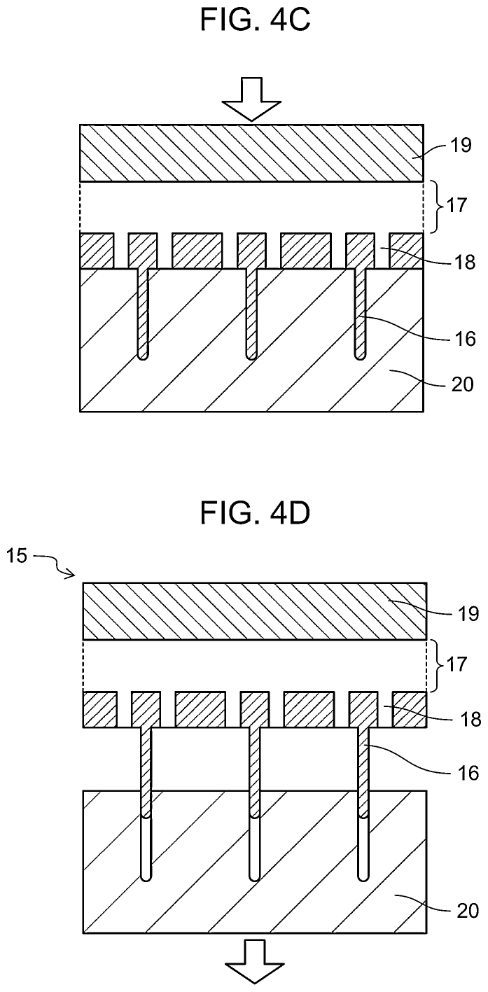

Next, a method for manufacturing imprint die 15 will be described with reference to FIGS. 4A to 4D.

As illustrated in FIG. 4A, resin 21 is coated to needle original plate 20 and is sandwiched by introduction path original plate 22. Resin 21 is cured in a state where introduction path dies 22a provided on introduction path original plate 22 come into contact with needle original plate 20, and introduction path original plate 22 is removed as illustrated in FIG. 4B. Needle dies 20a are provided in needle original plate 20, and needles 16 are formed by resin 21 filled in needle dies 20a. In addition, needle base portion 16a is formed on needle original plate 20. In needle base portion 16a, introduction paths 18 are formed in portions corresponding to introduction path dies 22a.

Subsequently, as illustrated in FIG. 4C, base 19 including flow path 17 is connected to needle base portion 16a. The connection is performed, for example, by adhesion or welding.

Thereafter, as illustrated in FIG. 4D, needle original plate 20 is peeled off to manufacture imprint die 15.

In addition, the diameter of needle 16 is set to be smaller than the diameter of opening 3b, and is preferably more than or equal to 1.5 μm. In addition, a height of needle 16 is set to be larger than the height of opening portion 3, and is preferably 10 times or less the diameter of needle 16.

As a result, it is possible to secure a die-cutting property of needle 16 with respect to needle original plate 20 and to obtain a shape of needle 16 suitable for a method for forming a bump to be described later.

For example, an acrylic resin, a silicone resin, an epoxy resin, or the like may be used as materials of resin 21 and needle 16 or introduction path 18.

Flow path 17 may be provided by forming wall portion 19a integrally with base 19 by using, for example, a method of machining Si, glass, stainless steel, or the like, or molding an acrylic resin, a polycarbonate resin, or the like. In addition, a resin may be coated to a plate-shaped base, and base 19 including wall portion 19a may be formed by imprinting.

For example, a metal material such as stainless steel, an inorganic material such as Si or glass, and an organic material such as epoxy resin are used as a material of base 19.

Note that, the above material is an example, and imprint die 15 may be manufactured by other methods and materials.

### <Method for Forming Bump>

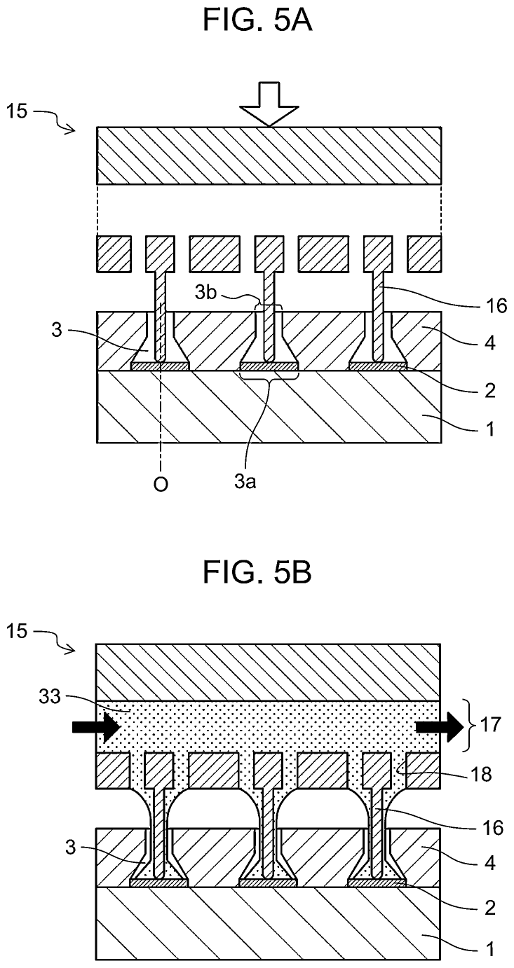

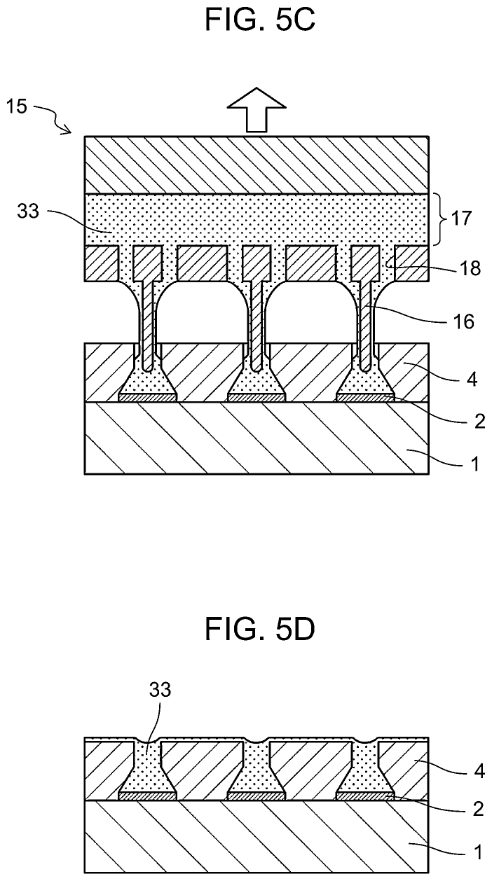

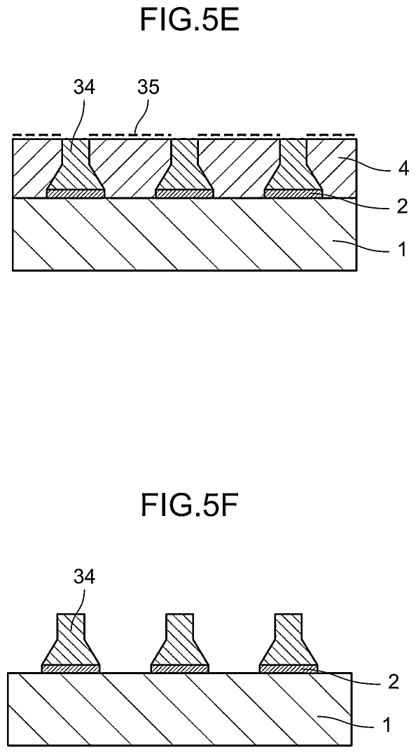

Next, a method for forming a sharp-edged fine metal bump using semiconductor element 1 and imprint die 15 will be described with reference to FIGS. 5A to 5F.

First, a step of inserting needle 16 illustrated in FIG. 5A is performed. Here, semiconductor element 1 on which electrode pads 2 and resist layer 4 including opening portions 3 is prepared. Further, imprint die 15 faces semiconductor element 1 with needles 16 facing downward. Needles 16 are aligned with opening portions 3, and imprint die 15 is lowered until distal ends of needles 16 come into contact with bottom surfaces of opening portions 3, that is, electrode pads 2.

At this time, at a point in time when the distal ends of needles 16 come near entrances of opening portions 3, fine vibration in a direction parallel to a front surface of semiconductor element 1 is preferably applied to one or both of semiconductor element 1 and imprint die 15. As a result, since the distal ends of needles 16 move relatively finely with respect to opening portions 3, the distal ends are easily guided to the positions of opening portions 3. As a result, it is possible to assist all needles 16 to enter opening portions 3. Since needles 16 are made of resin, the needles are guided to opening portions 3 by bending.

Subsequently, a filling step illustrated in FIG. 5B is performed. Here, metal particle dispersion 33 in which metal particles are dispersed in a solvent flows into flow path 17.

Metal particle dispersion 33 flows into introduction paths 18 by a capillary phenomenon, and is transferred onto electrode pads 2, which are the bottom surfaces of opening portions 3, along needles 16. Transferred metal particle dispersion 33 wets and spreads on electrode pads 2 due to surface tension. Accordingly, metal particle dispersion 33 is further drawn into opening portions 3. As a result, opening portions 3 are filled with metal particle dispersion 33.

A part of a wall surface of introduction path 18 may be shared with a side surface of needle 16. That is, a part of the wall surface of introduction path 18 may be connected to the side surface of needle 16 without a step.

In addition, introduction path 18 is preferably opened such that a length of an inner periphery thereof is 1 to 2 times a length of an outer periphery of needle 16. In addition, a height of introduction path 18 is preferably half or less of the height of needle 16.

The above description is useful for promoting the capillary phenomenon to allow metal particle dispersion 33 to flow into introduction path 18 from flow path 17 and to secure a drawing force for flowing out to needle 16 side.

In addition, the metal particles contained in metal particle dispersion 33 are preferably a metal having high electrical conductivity and easily diffused on electrode pad 2. Specific examples of the metal particles include Au, Cu, Ag, and Al. Further, a particle size of the metal particles is preferably in a range from 10 nm and 100 nm inclusive.

As a result, dispersibility of the metal particles in the solvent and inflow into opening portion 3 can be enhanced.

In addition, the solvent used in metal particle dispersion 33 is preferably an organic solvent whose viscosity is easily adjusted by a mixing ratio. For example, ethanol, ethylene glycol, and isopropyl alcohol are used as the solvent.

The viscosity of metal particle dispersion 33 is adjusted, and thus, an inflow speed of metal particle dispersion 33 into introduction path 18 and opening portion 3 can be adjusted.

In addition, metal particle dispersion 33 may contain components other than the metal particles and the solvent. For example, a surfactant may be contained.

Note that, as illustrated in FIG. 5C, a step of filling opening portion 3 with metal particle dispersion 33 is preferably performed while pulling up imprint die 15 in the middle of the step. By doing this, a contact area between needle 16 and filled metal particle dispersion 33 is reduced as compared with a case where needle 16 is pulled up after filling is performed while the needle is held within opening portion 3. As a result, liquid breakability of needle 16 with respect to metal particle dispersion 33 is improved, and a filling rate of metal particle dispersion 33 with respect to opening portion 3 can be improved.

In addition, when a contact angle of metal particle dispersion 33 with respect to electrode pad 2 is θ_{A} and a contact angle with respect to resist layer 4 (including the side wall of opening portion 3) is θ_{B}, a relationship of θ_{A}<θ_{B}<45° is preferably set.

As a result, even in a case where central axis O (see FIG. 5A) of opening portion 3 and a central axis of needle 16 are deviated and needle 16 comes into contact with the side wall of opening portion 3, metal particle dispersion 33 is guided onto electrode pad 2 due to a difference in surface tension. As a result, metal particle dispersion 33 is filled without leaving a gap in opening portion 3.

In addition, even though metal particle dispersion 33 overflows from opening portion 3, the metal particle dispersion wets and spreads on an upper surface of resist layer 4 as illustrated in FIG. 5D, and becomes an extremely thin film. As a result, swelling of metal particle dispersion 33 on opening portion 3 is suppressed, and a height of an important point of each opening portion 3 can be kept uniform.

Next, a sintering step illustrated in FIG. 5E is performed. Here, semiconductor element 1 in which opening portion 3 is filled with metal particle dispersion 33 is heated to 200° C. to 400° C. As a result, sharp-edged fine metal bump 34 is formed by volatilizing the solvent of metal particle dispersion 33 and sintering the metal particles.

Thereafter, semiconductor element 1 is immersed in a peeling solution of resist layer 4, and resist layer 4 is peeled off together with metal particles 35 remaining on the front surface of resist layer 4.

As a result, as illustrated in FIG. 5F, sharp-edged fine metal bump 34 can be formed on each of the plurality of electrode pads 2 provided in semiconductor element 1.

Note that, in the step of FIG. 5E, heat treatment to volatilize the solvent of metal particle dispersion 33 may be performed without completing sintering. In this case, subsequently, after resist layer 4 is peeled off in the step of FIG. 5F, heat treatment is performed again to complete sintering.

According to the above method, sharp-edged fine metal bump 34 having a stable shape can be formed on the plurality of electrode pads 2 provided in semiconductor element 1 regardless of the position, density, and the like of electrode pads 2.

In addition, according to this method, since metal particle dispersion 33 is sintered on electrode pad 2, sharp-edged fine metal bump 34 is directly formed on electrode pad 2. Accordingly, a seed layer that is essential in a case where the bump is formed by the plating method is unnecessary, and a change in the bump shape due to the removal of the seed layer can be avoided.

Note that, an example in which sharp-edged fine metal bump 34 is formed on electrode pad 2 provided in semiconductor element 1 has been described above. However, a circuit board can be used instead of semiconductor element 1. In this case, semiconductor element 1 may be replaced with the circuit board in the above description. That is, semiconductor element 1 is an example of an object, and the circuit board is another example of the object.

### Modification

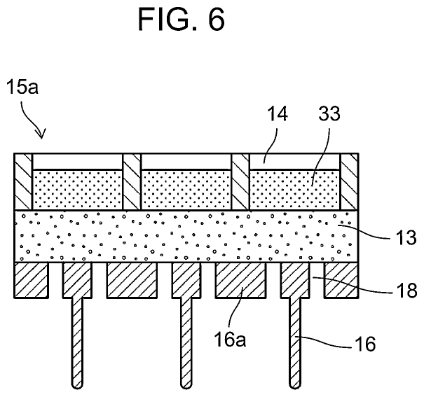

Next, a modification of the present exemplary embodiment will be described. In the present modification, imprint die 15a illustrated in FIG. 6 is used.

In imprint die 15 illustrated in FIGS. 3A and 3B, flow path 17 is provided for allowing metal particle dispersion 33 to flow into introduction path 18. On the other hand, in imprint die 15a of FIG. 6, porous body 13 is provided instead of flow path 17. In addition, a plurality of liquid layers 14 for retaining metal particle dispersion 33 are provided on porous body 13.

Porous body 13 has a large number of pores, and can transmit metal particle dispersion 33. Accordingly, metal particle dispersion 33 is transmitted through porous body 13 from liquid layer 14 and is introduced into introduction path 18 provided in needle base portion 16a.

A method for forming sharp-edged fine metal bump 34 using imprint die 15a is similar to the method described in FIGS. 5A to 5F.

Porosity of porous body 13 is adjusted, and thus, an inflow speed of metal particle dispersion 33 can be adjusted. A pore diameter of porous body 13 desirably corresponds to a diameter of the metal particle contained in metal particle dispersion 33. For example, the diameter is desirably from 100 times and 200 times inclusive of the diameter of the metal particle.

A thickness of porous body 13 is preferably from 0.1 mm and 1 mm inclusive. As a result, strength and flexibility of porous body 13 can be secured, and porous body 13 can be brought into close contact with needle base portion 16a. As a result, flowability of metal particle dispersion 33 into introduction path 18 is improved.

Examples of a material of porous body 13 include ceramic materials such as alumina, stone materials such as pumice, metals such as Al and stainless steel, and organic materials such as polyurethane.

Note that, in FIG. 6, porous body 13 is provided to cover the entire surface of needle base portion 16a. However, alternatively, the porous body may be partially provided only immediately above introduction path 18.

### INDUSTRIAL APPLICABILITY

Since the plurality of sharp-edged fine metal bumps can be formed on the semiconductor element and the circuit board, the bump manufacturing method of the present disclosure is also useful for mounting the semiconductor element in which the number of pins and the pitch are increased.

### REFERENCE MARKS IN THE DRAWINGS

1 semiconductor element
2 electrode pad
3 opening portion
3a opening
3b opening
4 resist layer
5 imprint die
13 porous body
14 liquid layer
15 imprint die
15a imprint die
16 needle
16a Needle base portion
17 flow path
18 Introduction path
19 base
19a wall portion
20 needle original plate
20a needle die
21 resin
22 Introduction path original plate
22a introduction path die
33 metal particle dispersion
34 sharp-edged fine metal bump
35 metal particle
41 resin layer
43 resist coating layer
43a opening portion
45 die
45a protrusion

1. A bump manufacturing method for manufacturing a bump on an object, the method comprising:
preparing an object that includes an electrode pad and a resist layer including an opening portion on the electrode pad;
inserting a needle having a diameter smaller than an opening diameter of the opening portion to the opening portion to come into contact with the electrode pad;
filing the opening portion with a metal particle dispersion by transferring the metal particle dispersion to the needle; and
sintering the metal particle dispersion filling the opening portion.

2. The bump manufacturing method according to claim 1, wherein the filling of the metal particle dispersion is performed while the needle is pulled out of the opening portion.

3. The bump manufacturing method according to claim 1, wherein
the needle is provided in an imprint die, and
the imprint die includes an introduction path for introducing the metal particle dispersion to the needle near a root of the needle.

4. The bump manufacturing method according to claim 1, wherein
the needle is provided in an imprint die, and
the imprint die incudes a porous body for introducing the metal particle dispersion to the needle.

5. The bump manufacturing method according to claim 1, wherein, in the inserting of the needle, at least one of the object and the needle is vibrated in a direction parallel to a front surface of the object.

6. The bump manufacturing method according to claim 1, wherein the object is a semiconductor element.

7. The bump manufacturing method according to claim 1, wherein the object is a circuit board.

8. The bump manufacturing method according to claim 1, wherein the object includes a plurality of the electrode pads each being the electrode pad.

9. An imprint die comprising:
a needle; and
an introduction path that supplies a liquid to the needle.

10. The imprint die according to claim 9, wherein
the needle is attached to one surface of a needle base portion, and
the introduction path is provided to penetrate through the needle base portion near the needle.

11. The imprint die according to claim 9, further comprising a plurality of the needles each being the needle.
